(19) United States
(12) Patent Application Publication
(10) Pub. No.: US 2023/0352912 A1
(43) Pub. Date: Nov. 2, 2023

(54) BURIED HETEROSTRUCTURE SEMICONDUCTOR LASER AND METHOD OF MANUFACTURE

(71) Applicant: NATIONAL RESEARCH COUNCIL OF CANADA, Ottawa (CA)

(72) Inventors: Omid Salehzadeh EINABAD, Orleans (CA); Anthony SPRINGTHORPE, Richmond (CA); Daniel BONNEAU, Stittsville (CA); Grzegorz PAKULSKI, Woodlawn (CA); Muhammad MOHSIN, Ottawa (CA)

(21) Appl. No.: 18/245,727

(22) PCT Filed: Sep. 17, 2021
(86) PCT No.: PCT/IB2021/058512

§ 371 Date: Mar. 17, 2023

Related U.S. Application Data
(60) Provisional application No. 63/080,189, filed on Sep. 18, 2020.

(51) Int. Cl. H01S 5/227; H01S 5/22

(52) U.S. Cl. CPC H01S 5/2275; H01S 5/2223; H01S 5/2272; H01S 5/0021

(57) ABSTRACT

A heterostructure laser is provided comprising an epitaxially grown substrate of first dopant type, an active region and layer of second dopant type, a narrow mesa having less than 20% open area and a side wall slope of less than 85 degrees, wherein said narrow mesa is etched through the active region and layer of second dopant type using in-situ MOCVD, a plurality of current blocking layers, an overclad layer and a contact layer of second dopant type, and an isolation mesa incorporating the narrow mesa, wherein the isolation mesa is etched through the active region, layer of second dopant type and plurality of current blocking layers and wherein the plurality of current blocking layers is grown without exposure to oxygen.

### BACKGROUND OF THE INVENTION

### 1. Field of the Invention

This invention relates in general to semiconductor lasers, and more particularly to heterostructure devices, such as buried heterostructure (BH) lasers/semiconductor optical amplifiers (SOAs), and methods of manufacture thereof.

### 2. Description of the Related Art

An SOA is an amplifier, while a laser is a source of a coherent light with a grating feature to select a specific lasing wavelength. An SOA may be a laser with anti-reflection coatings, but can also be a laser with a mesa stripe that is not at normal incidence to the mirrors. A laser requires optical feedback from end mirrors, while in an SOA the reflections from end facets must be avoided. Therefore, in SOAs the end facets often include antireflective coatings and furthermore, the waveguide grating may be tilted at a 6-10 degree angle to further suppress residual reflections from the end facets.

Both lasers and SOAs may be used as components in optical transceivers for digital communications products and radar. For example, photonic chips are used as on-chip lasers as optical sources for optical communication systems and free-space communications.

A semiconductor lasers and SOAs include a p-n diode structure placed inside an optical cavity. Under forward bias, charge carriers are injected into a thin active layer providing an optical gain. The performance of a semiconductor laser or SOA can be improved by including a buried heterostructure for providing optical and carrier confinement, whilst also offering high thermal performance, optimal beam shapes and low noise, semiconductor, optical amplification.

However, fabrication of high reliability heterostructure devices such as BH lasers and SOAs is a challenge due to spontaneous oxidation of the etched walls of the mesa structure prior to growth of current blocking layers, which acts as a mask during the regrowth process.

### SUMMARY OF THE INVENTION

A metal organic chemical vapor deposition (MOCVD) in-situ etching process is set forth for defining the narrow mesa region of a heterostructure devices, immediately followed by growth of the blocking layers.

According to an aspect of the present specification, a heterostructure laser device is set forth comprising an epitaxially grown substrate of first dopant type, active region and layer of second dopant type; a narrow mesa having less than 20% open area and a side wall slope of less than 85 degrees, wherein said narrow mesa is etched through the active region and layer of second dopant type using in-situ MOCVD; a plurality of current blocking layers; an overclad layer and a contact layer of second dopant type; and an isolation mesa incorporating the narrow mesa, wherein the isolation mesa is etched through the active region, layer of second dopant type and plurality of current blocking layers.

According to a further aspect, a method of fabricating a heterostructure device is set forth, comprising growing epitaxial layers of a substrate of first dopant type, an active region and a layer of second dopant type; patterning a mask and etching a narrow mesa through the active region and layer of second dopant type using in-situ MOCVD; growing a plurality of current blocking layers using in-situ MOCVD and without exposure to oxygen; removing the mask and growing an overclad layer and a contact layer of second dopant type; and etching an isolation mesa through the active region, layer of second dopant type and plurality of current blocking layers such that the isolation mesa incorporates the narrow mesa.

These together with other aspects and advantages are more fully set forth below, reference being had to the accompanying drawings forming a part hereof, wherein like numerals refer to like parts throughout.

### BRIEF DESCRIPTION OF THE DRAWINGS

FIGS. 1(a) to 1(f) show stages of fabrication of a BH laser, according to the prior art.

FIGS. 2A(a) to 2A(e) show stages of fabrication of a BH laser, according to an embodiment of the invention.

FIG. 2B is an extension of FIG. 2A(b2) showing adjacent devices separated by a large unetched area.

FIG. 3 shows steps in a process for fabricating the BH laser for FIGS. 2(a) to (d), according to an embodiment.

FIGS. 4(a) to (d) are SEM images showing structures produced according to an embodiment of the invention, FIGS. 4(a) and (b), as compared to the prior art, FIGS. 4(c) and (d).

FIG. 5 is a SEM image of a heterostructure (BH) laser produced according to an embodiment of the invention.

FIG. 6 is a graph showing life test data for a heterostructure (BH) laser produced according to an embodiment of the invention.

### DETAILED DESCRIPTION OF THE PREFERRED EMBODIMENTS

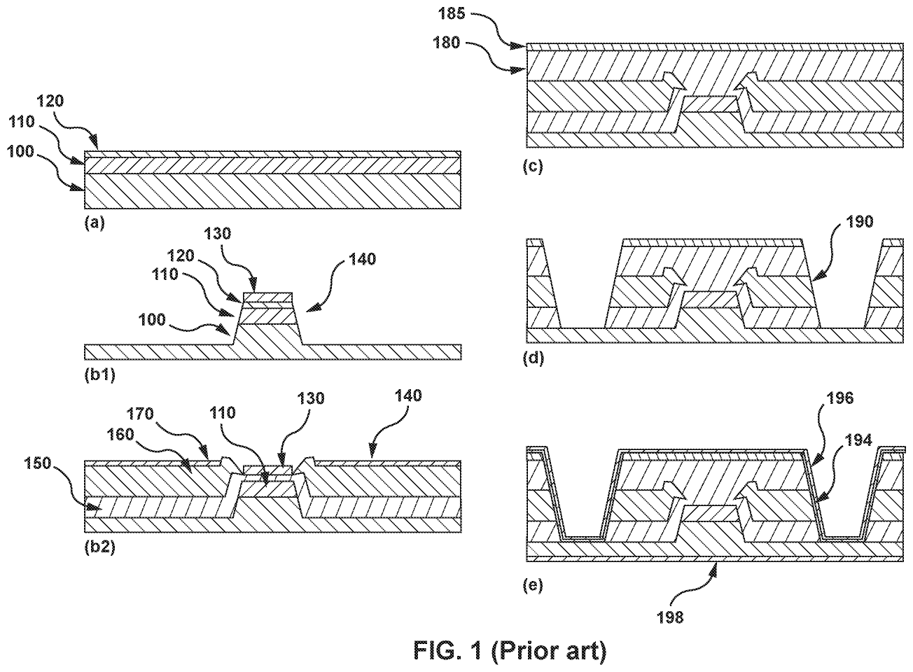

FIGS. 1(a) to 1(f) show stages of fabrication of a BH FP (Fabry-perot)) laser, according to the prior art. First, a wafer of stacked layers, including an n-type substrate 100, active region 110 and p-type layer 120, is epitaxially grown on the substrate (FIG. 1(a)). Then, a dielectric mask 130 is patterned and the wafer is etched through the active region 110 forming a narrow mesa 140 (FIG. 1(b)). Conventionally, the etching process resulting in the structure of FIG. 1(b) is either a dry reactive ion etch or a wet etch. Next, the wafer(s) are loaded in a growth tool and blocking layers 150 and 160 are grown as a p-n junction, followed by a further thin p-type layer 170, resulting in the p-n-p- layer sequence shown in FIG. 1(c). Conventionally, the growth of blocking layers resulting in the structure of FIG. 1(c) is carried out after a wet preclean process to remove etch damage and/or surface oxide. Next, the dielectric mask 130 is removed and after a preclean process, the wafers are loaded in a growth tool and a final p-type overclad layer 180 and p-contact layer 185 are grown such that the p-type layers 170 and 180 merge to form an overall n-p-n-p structure (FIG. 1(d)).Then, the wafer is patterned and an isolation etch is carried out through layers 150, 160, 170, 180 and 185 to form a larger mesa 190 (FIG. 1(e)). Conventionally, this etch is either carried out via a reactive ion etch process or a wet etch process. Finally, the n-type substrate 100 is thinned and dielectric cladding layer 194, p-metal deposition layer 196 and backside n-metal deposition layer 198 are deposited (FIG. 1(f)).

According to the prior art, the narrow mesa etch (FIG. 1(b)) and isolation etch (FIG. 1(e)) and be performed as either dry-dry processes, respectively; wet-wet processes, respectively or wet-dry processes, respectively.

The main drawback with dry-dry processes is that the fabricated devices are not reliable as a result of etch damage caused by the dry etch process, while the main drawback with the wet-wet or wet-dry processes is that the wet etch of the narrow mesa 140 and wide mesa 190 introduces large variations in the widths of the mesas 140 and 190, leading to device failure and yield loss.

Another major issue with all three conventional methods dry-dry, wet-wet and wet-dry), is exposure of the sidewalls of the narrow mesa 140 to air prior to growth of the blocking layers. This results in a sidewall oxidation, which deteriorates the performance of the laser. This issue is more critical where the active region 110 contains aluminum.

As discussed above, a MOCVD in-situ etching process is set forth herein for defining the narrow mesa region 140, immediately followed by growth of the blocking layers 150, 160, 170 without exposure to air. In an embodiment, a combination of dry and wet etch processes are used to define the isolation mesa 190.

MOCVD is a chemical vapour deposition method used for growing crystalline layers to create complex semiconductor multilayer structures. In contrast to molecular-beam epitaxy, the growth of crystals using MOCVD is by chemical reaction and not physical deposition. The process takes place in a nitrogen atmosphere at moderate pressures (e.g. 10 to 760 Torr).

Unlike the conventional fabrication process discussed with reference to FIGS. 1(a) to 1(f), where the narrow mesa 140 etch is performed prior to transferring the wafer to MOCVD such that the mesa side wall becomes oxidized through exposure to air, according to the process set forth below the wafer is etched using MOCVD immediately thereafter the blocking layers are grown so that there is no sidewall oxygen exposure.

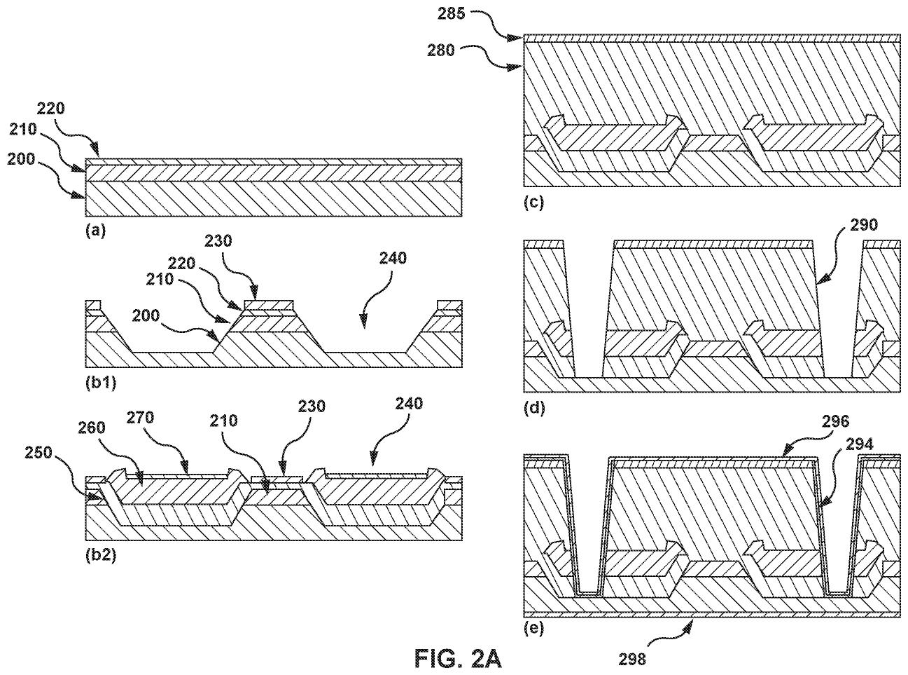

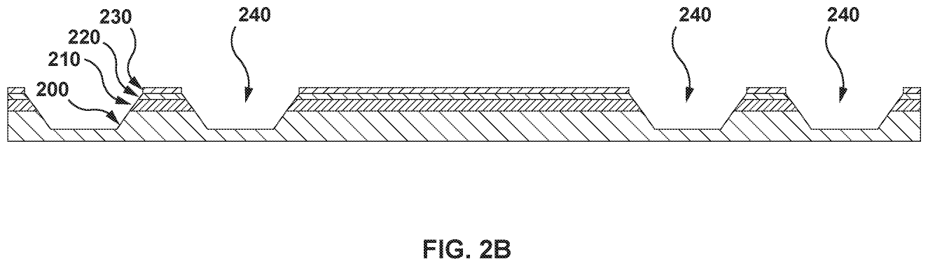

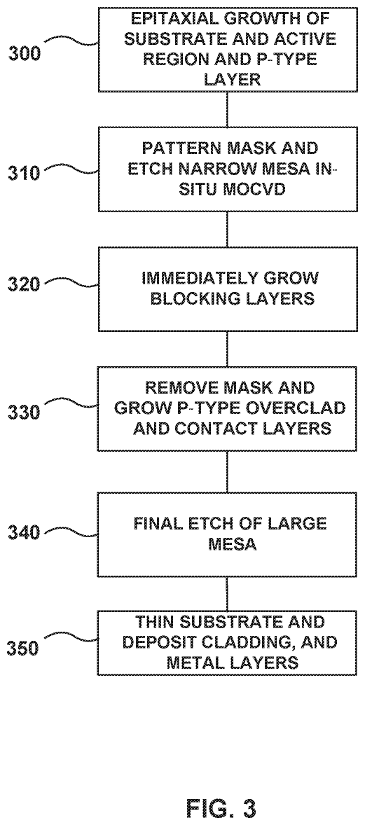

FIGS. 2A(a) to 2A(d) and the method of FIG. 3 show stages of fabrication of a BH FP laser, according to an embodiment of the invention. At 300, a wafer of stacked of layers, including an substrate 200 of first dopant type (e.g. n-type), active region 210 and layer 220 of second dopant type (e.g. p-type), is epitaxially grown on the substrate (FIG. 2A(a)). At 310, a dielectric mask 230 is patterned and the wafer is etched through the active region 110 forming a narrow mesa 240 (FIG. 2A(b1)). FIG. 2B is an extension of FIG. 2A(b1) showing adjacent devices of width 30-60 um separated by 250-500 um. Compared to the structure shown in FIG. 1(b), wherein the narrow mesa etch process results in over 90% open area and a side wall slope of about 85 degrees for mesa 140 (characteristic of downward etching layer-by-layer crystalographically), the open area resulting from the MOCVD in-situ etch process of the invention is reduced to below 20% and produces a more gradual side wall slope of the mesa 240. In other words, whereas in the conventional etching procedure discussed above with reference to FIG. 1(b), the mesa 140 is centered on a large open area such that the open area is approximately ˜99% etched, according to the ‘in-situ’ process of FIGS. 2A(b2) and 2B, the mesas 240 are in pairs separated by a large area that is not etched. For example, a mesa 240 having a top width of 5 um and 20 um openings in the dielectric mask, separated by 500 um, has an open area of 40/500=˜12.5%.

At 320, the blocking layers 250, 260 and 270, are immediately grown sequentially to step 310 within the MOCVD chamber, without any need to transfer the wafer and therefore no exposure to oxygen, resulting in the n-p-n- layer sequence shown in FIG. 2A(b2). At 330, the wafer is removed from the MOCVD chamber and the dielectric mask 230 is removed ex situ. The wafer is then returned to the chamber and a final p-type overclad layer 280 and p-contact layer 285 are grown (FIG. 2A(c)) in a separate MOCVD step. Then, at 340, the wafer is patterned and an isolation etch is carried out through layers 250, 260, 270, 280 and 285 to form a larger mesa 290 (FIG. 2A(d)). Conventionally, this etch is either carried out via a reactive ion etch process or a wet etch process. Finally, at 350 n-type substrate 200 is thinned and dielectric cladding layer 294, p-metal deposition layer 296 and backside n-metal deposition layer 298 are deposited to form a deeper mesa (FIG. 2A(e)).

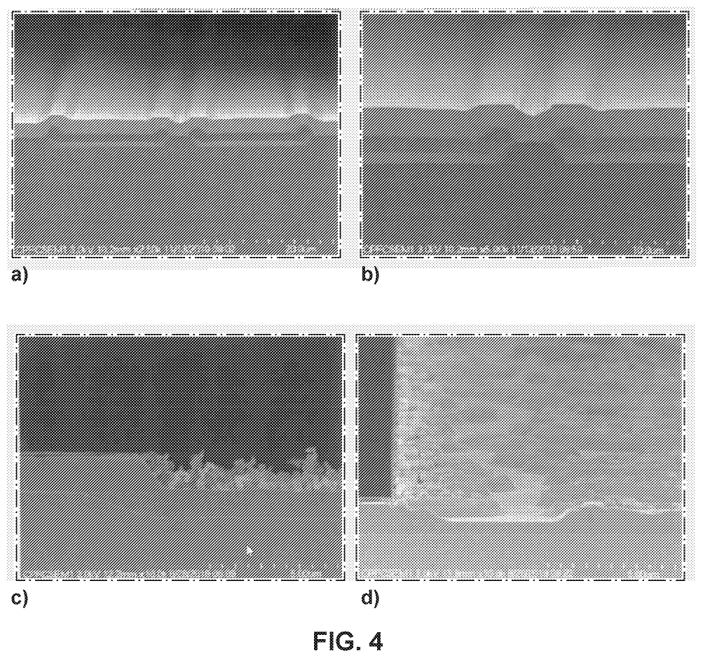

As shown in FIGS. 4(a) and 4(b), which are scanning electron microscope (SEM) images of the resulting structures corresponding to FIG. 2A(b2) and 2A(c), respectively, the in-situ etch results in defect free surfaces of nearly atomic flatness in contrast to FIGS. 4(c) and 4(d), which are scanning electron microscope (SEM) images of the resulting structures corresponding to FIGS. 1(b) and 1(c), respectively, which shows a very rough surface and evidence of etch damage due to ion bombardment on etched surfaces. The total mask loading (total oxide area) according to the prior art process is less than 10%, whereas oxide loading according to the process of the invention is about 80% producing a much smoother etch profile.

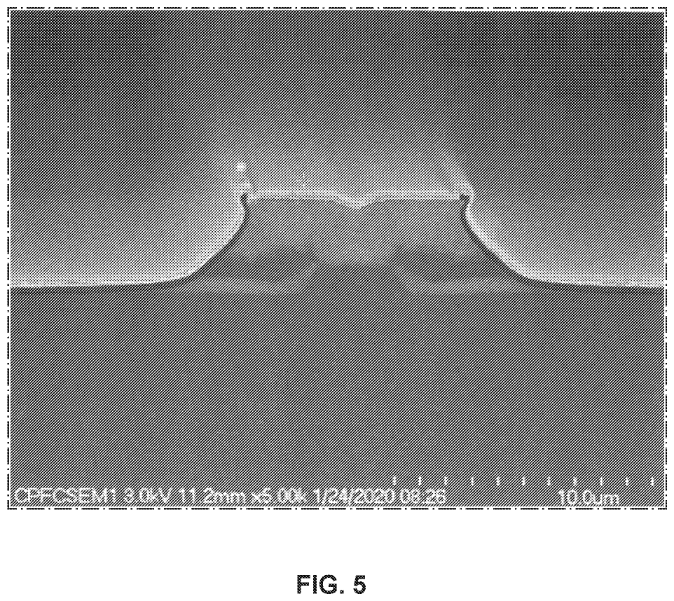

A SEM image of the resulting heterostructure (BH) laser according to an embodiment of the invention is shown in FIG. 5.

Performance data for experimental devices (10 uncoated FP BH lasers) produced according to the invention, is provided in Table I, indicating an excellent performance of the fabricated devices.

| Cavity | | | | Peak | Cavity | |
|---|---|---|---|---|---|---|
| length | I [symbol] | Efficiency | R [symbol] | wavelength | Loss | |
| (um) | (mA) | (W/A) | Ω | (nm) | (1/cm) | IQE |
| 2000 | 16.462 | 0.135 | 1.416 | 1562 | 10.373 | 0.9325 |
| 1500 | 13.555 | 0.163 | 1.722 | 1558 | | |
| 1000 | 10.426 | 0.198 | 1.999 | 1555 | | |

[symbol]

indicates data missing or illegible when filed

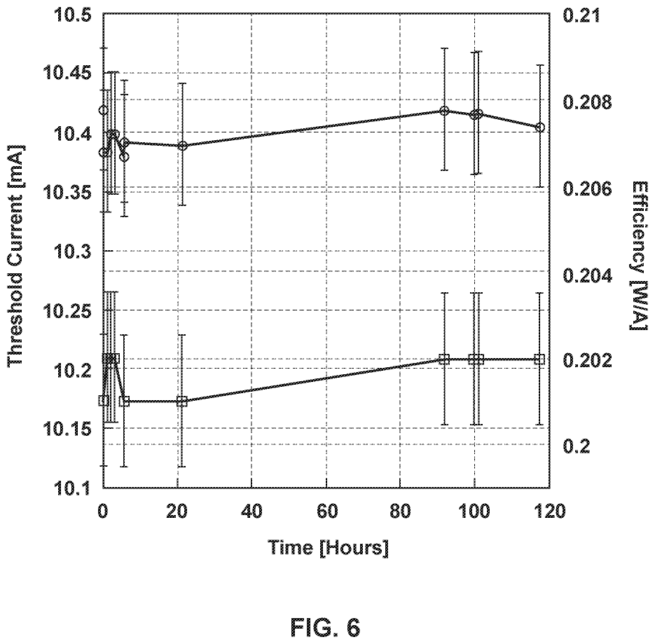

Life test data of a fabricated FP BH laser produced according to the invention is shown in FIG. 6, with (L=1 mm, bias=80 mA (0=100 h) to 250 mA (100-117.5 h), T_{aging}=80 C, Tₜₑₛₜ=20 C, indicating that the fabricated BH lasers are extremely reliable.

The many features and advantages of the invention are apparent from the detailed specification and, thus, it is intended by the appended claims to cover all such features and advantages of the invention that fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

What is claimed is:

1. A heterostructure device comprising:
an epitaxially grown substrate of first dopant type, active region and layer of second dopant type;
a narrow mesa having less than 20% open area and a side wall slope of less than 85 degrees, wherein said narrow mesa is etched through the active region and layer of second dopant type using in-situ MOCVD;
a plurality of current blocking layers;
an overclad layer and a contact layer of second dopant type; and
an isolation mesa incorporating the narrow mesa, wherein the isolation mesa is etched through the active region, layer of second dopant type and plurality of current blocking layers.

2. The heterostructure device of claim 1, wherein the first dopant type is n-type and the second dopant type is p-type.

3. The heterostructure device of claim 2, wherein the current blocking layers conform to a p-n-p layer sequence.

4. A method of fabricating a heterostructure device, comprising:
growing epitaxial layers of a substrate of first dopant type, an active region and a layer of second dopant type;
patterning a mask and etching a narrow mesa through the active region and layer of second dopant type using in-situ MOCVD;
growing a plurality of current blocking layers using in-situ MOCVD and without exposure to oxygen;
removing the mask and growing an overclad layer and a contact layer of second dopant type;
etching an isolation mesa through the active region, layer of second dopant type and plurality of current blocking layers such that the isolation mesa incorporates the narrow mesa; and
depositing metal contact layers.

5. The method of claim 4, wherein the first dopant type is n-type and the second dopant type is p-type.

6. The method of claim 5, wherein the current blocking layers conform to a p-n-p layer sequence.

7. The method of claim 3, wherein etching the isolation mesa etch is carried out via one of either a reactive ion etch process or a wet etch process.

8. The method of claim 3, further including a preclean process after the dielectric mask is removed and before the overclad layer contact layer are grown.

9. A wafer of heterostructure devices, comprising:
a plurality of heterostructure devices arranged in pairs, each heterostructure device including
a substrate of first dopant type,
an active region, and
a layer of second dopant type epitaxially grown on the substrate;
a narrow mesa having less than 20% open area and a side wall slope of less than 85 degrees, wherein said narrow mesa is etched through the active region and layer of second dopant type using in-situ MOCVD;
a plurality of current blocking layers;
an overclad layer and a contact layer of second dopant type; and
an isolation mesa incorporating the narrow mesa, wherein the isolation mesa is etched through the active region, layer of second dopant type and plurality of current blocking layers, wherein each pair of heterostructure devices is separated by an unetched area.

10. The wafer of heterostructure devices according to claim 9, wherein the width of each pair of heterostructure devices is 30-60 um and the unetched area is 250-500 um.

11. The wafer of heterostructure devices according to claim 9, wherein the first dopant type is n-type and the second dopant type is p-type.

12. The wafer of heterostructure devices according to claim 11, wherein the current blocking layers conform to a p-n-p layer sequence.
